(19) United States
(12) Patent Application Publication
(10) Pub. No.: US 2016/0109625 A1
(43) Pub. Date: Apr. 21, 2016

(54) SUPPORT FOR A FLEXIBLE OLED

(71) Applicant: Saint-Gobain Performance Plastics Corporation, Aurora, OH (US)

(72) Inventors: Denis Guimard, Paris (FR); Simon Mazoyer, Paris (FR); Charles Leyder, Paris (FR)

(21) Appl. No.: 14/885,304

(22) Filed: Oct. 16, 2015

(30) Foreign Application Priority Data
Oct. 21, 2014 (FR) 1460124
Oct. 29, 2014 (FR) 1460383

(51) Int. Cl. G02B 5/02; C09J 5/00; B32B 17/06; G02B 5/30; B32B 37/12; B32B 37/14; F21V 5/00; H01L 51/52; B32B 27/36

(52) U.S. Cl. CPC G02B 5/0242; H01L 51/5246; C09J 5/00; B32B 17/064; B32B 27/36; B32B 37/12; B32B 37/14; G02B 5/0278; F21V 5/002; G02B 5/3083; H01L 2251/5338; H01L 2251/5369; C09J 2467/006; B32B 2307/418; B32B 2457/206; F21Y 2101/02

(57) ABSTRACT

A laminated support for flexible optoelectronic devices can include, in the order indicated, the following elements:
a mineral glass sheet having a thickness of 300 microns or less and a refractive index n₁ below 1.65, preferably below 1.60, ideally below 1.55,
a diffusing adhesive layer,
a uniaxially or biaxially stretched transparent organic polymer film with a refractive index n₃, measured in a direction along the film's plane, of 1.7 or more.

### CROSS-REFERENCE TO RELATED APPLICATIONS

The current application claims priority to French Patent Application No. 1460124, filed Oct. 21, 2014, entitled “SUPPORT FOR A FLEXIBLE OLED”, naming as inventors Denis Guimard et al., and French Patent Application No. 1460383, filed Oct. 29, 2014, entitled “SUPPORT FOR A FLEXIBLE OLED”, naming as inventors Denis Guimard et al., which applications are incorporated by reference herein in their entireties.

### FIELD OF THE DISCLOSURE

This invention relates to a diffusing laminated support for flexible optoelectronic devices, and a method for the preparation of such a support.

### RELATED ART

An Organic Light Emitting Diode (OLED) is an optoelectronic device comprising two electrodes of which at least one is transparent to visible light, and one stack of thin layers comprising at least one Electroluminescent Layer (EL layer). This electroluminescent layer is sandwiched between at least, on one the one hand, an Electron Injection or Electron Transport Layer (EIL or ETL) located between the EL layer and the cathode and, on the other hand, a Hole Injection or Hole Transport Layer located between the EL layer and the anode.

OLEDs comprising one transparent electrode support and one transparent electrode in contact therewith are conventionally called substrate emitting OLEDs or bottom emitting OLEDs. The transparent electrode in this case is typically the anode. Similarly, OLEDs comprising an opaque electrode support are called Top Emitting OLEDs, emission occurring through the transparent electrode that is not in contact with the support, generally the cathode.

OLEDs are used in the field of display and lighting. OLEDs have been proposed that are on flexible supports that can include a laminate of transparent plastic sheets, a laminate of very thin sheets of mineral glass (<300 microns), henceforth called Ultra Thin Glass (UTG), a laminate that includes an ultra thin glass sheet bonded to an organic polymer sheet, where the anode is formed on the ultra thin glass sheet. Each of these laminates has at least one problem. With respect to the UTG/polymer laminate, only a small fraction of the light produced by the electroluminescent layer of the OLED is emitted through the laminate support because the optical index of a glass substrate (n_{glass}=1.5) is lower than that of the organic layers (n_{EL}=1.7-1.9) and of the transparent anode (n_{anode}=1.9 to 2.1). Most of the light (around 50%) is trapped in these high refractive index layers as in a waveguide and is absorbed after a certain number of reflections. For a laminate that includes UTGs, a similar phenomenon occurs at the interface between the glass of the substrate (n_{glass}=1.5) and the air (nₐᵢᵣ=1.0) and traps around an additional 20% of the light emitted by the electroluminescent layer.

Reduction of this phenomenon of trapping light in the high-index layers (total internal reflection) is known to be achieved by inserting between the glass substrate and the transparent anode a means of extracting the light, formed for example by a high-refractive-index layer containing diffusing particles or by means of a rough, diffusing interface between the substrate and anode. Such a diffusing layer is typically called an Internal Extraction Layer (IEL) in contrast to a diffusing layer located further towards the outside at the glass/air interface, typically called the External Extraction Layer (EEL).

### BRIEF DESCRIPTION OF THE DRAWINGS

Embodiments are illustrated by way of example and are not limited in the accompanying figures.

FIG. 1 represents a first embodiment of the laminated support,

FIG. 2 represents a second embodiment of the laminated support, and

FIG. 3 represents a fourth embodiment of the laminated support.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

As used in this specification, refractive indices are measured at 550 nm.

Haze values are determined in accordance with Standard ASTM D1003 (Procedure A).

The term “particle size” refers to a median particle size as determined using a scanning electron microscope micrograph using a statistically significant sample size, except as explicitly stated to the contrary.

The terms “on,” “overlying,” and “over” may be used to indicate that two or more elements are in direct physical contact with each other. However, “over” may also mean that two or more elements are not in direct contact with each other. For example, “over” may mean that one element is above another element but the elements do not contact each other and may have another element or elements in between the two elements.

Group numbers corresponding to columns within the Periodic Table of Elements based on the IUPAC Periodic Table of Elements, version dated Jan. 21, 2011.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about”, “approximately”, or “substantially” is intended to mean that a value of a parameter is close to a stated value or position. However, minor differences may prevent the values or positions from being exactly as stated. Thus, differences of up to ten percent (10%) for the value are reasonable differences from the ideal goal of exactly as described.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the OLED, and more particularly, OLED support arts.

An internal extraction layer (IEL) can be inserted between the ultra thin glass sheet and the plastic film of a glass/plastic laminated support. For this IEL to operate efficiently, the Applicant
has inverted the relative arrangement of the two layers, i.e., has placed the ultra thin glass sheet on the very outside of the optoelectronic device and the plastic sheet further towards the inside in contact with the an electrode layer, counter to the state of the art, and
has set a high refractive index for the plastic sheet in order to reduce the effect of internal total reflection at the electrode/plastic interface.

A laminated support for flexible optoelectronic devices can comprise, in the order indicated, the following elements:
a mineral glass sheet (1) having a thickness of 300 microns or less and a refractive index n₁ below 1.65, preferably below 1.60, ideally below 1.55,
a diffusing adhesive layer (2),
a uniaxially or biaxially stretched transparent organic polymer film (3) with a refractive index n₃, measured in a direction along the film's plane, of 1.7 or more.

In an optoelectronic device containing a laminated support according to the concepts described herein, the diffusing adhesive layer plays the role of a light extraction layer (IEL).

Several embodiments can be envisaged without departing from the scope of the present invention:
The IEL can be a layer formed of a high-index adhesive in which diffusing elements are dispersed (first embodiment),
the IEL can be formed of two sub-layers of adhesive having different refractive indexes, the interface between the two sub-layers having sufficient texturization to render it diffusing (second embodiment),
the third embodiment differs from the above-mentioned second embodiment in that the high-index sub-layer also contains diffusing elements, the diffusing nature of the adhesive layer thus being ensured both by the interface and the diffusing elements in the high-index sub-layer, and
the fourth embodiment differs from the third embodiment in that the interface between the two sub-layers is not textured, the diffusing nature of the diffusing adhesive layer being ensured solely by the diffusing elements dispersed in the high-refractive-index sub-layer.

Combinations and variations of these embodiments can of course be envisaged provided that the adhesion between the glass sheet and the plastic sheet remains satisfactory for the use envisaged.

Mineral glass sheets that can be used are available on the market, for example under the trade names of Willow Glass (Corning), AF 32® eco and D 263® T eco (Schott Glass), or OA-10G (Nippon Electric Glass). These are ultra thin glass sheets manufactured using the “fusion draw” process described, for example, in patents U.S. Pat. No. 3,338,696 or U.S. Pat. No. 3,682,609, or by a process of blow-moulding a tubular preform, as described in EP 2 066 592. The thickness of the UTG sheets can be in a range of 10 microns to 250 microns, 20 microns to 200 microns, or 30 microns to 150 microns.

The organic polymer film can be a film stretched in one or two directions. Uniaxially stretched films, also called uniaxially oriented films, are usually stretched in the lengthwise direction of the strip when exiting the extruder. Biaxially stretched films, also called biaxially oriented films, are stretched in the lengthwise direction of the strip and in the widthways direction of the strip when exiting the extruder.

Stretching in one or two directions generates a birefringence of the film. Uni- or biaxially oriented films thus generally have three different refractive indexes measured respectively:
in the first stretching direction (length of the strip),
in a direction perpendicular to this first stretching direction (width of the strip), this direction being the same as the second stretching direction for a bi-oriented film, and
in the thickness of the film.

At least one of the two first refractive indexes—measured in a direction in the plane of the film—is 1.7 or more, it being possible for the refractive index measured in the direction of the thickness of the film to be significantly lower than 1.7, indeed lower than 1.6, and even lower than 1.5. Preferably, the two refractive indexes measured in a direction in the plane of the film are 1.7 or higher. In a particular embodiment, none of the refractive indices is greater than 2.4.

The organic polymer film may be a nanocomposite, in other words, it may contain a certain proportion of mineral nanoparticles added in order to increase the film's refractive index. These particles can be sufficiently small, generally smaller than 50 nm, in order to keep Rayleigh scattering to a minimum. In a particular embodiment, the particles may be at least 2 nm. High refractive index nanoparticles likely to increase the refractive index of the organic polymer film are, for example, TiO₂ or ZrO₂ nanoparticles, preferably ZrO₂ nanoparticles. The proportion of the film's nanoparticles is preferably less than 50% by volume, in particular less than 30% by volume, ideally 20% by volume. In a particular embodiment, the film's nanoparticles may be at least 1% by volume.

In a preferred embodiment, the organic polymer film is free of high refractive index nanoparticles, light scattering particles, or both. Such organic polymers with an intrinsically high refractive index are known and marketed. These are preferably polyesters or copolyesters based on 2,6-naphthalenedicarboxylic acid, ethylene glycol acid, and possibly one or more comonomers, such as terephthalic acid. The organic polymer film may also include a mixture of poly(ethylene naphthalate) (PEN) and poly(ethylene terephthalate) (PET). The films are crystalline or semi-crystalline. They are available on the market for example under the trade names Teonex® Q51 and Teonex® Q65 HA marketed by the DuPont Teijin Films Company.

The ultra thin mineral glass sheet and the organic polymer film are bonded together by means of a diffusing adhesive layer. The diffusing nature of this adhesive layer is due to the presence of diffusing elements dispersed in a matrix having a different refractive index to that of the diffusing elements and/or to the texturization of an interface between two transparent layers having different indexes. The matrix in which the diffusing elements will be dispersed will have a refractive index that is higher or the same as that of the uniaxially stretched or biaxially stretched film of a transparent organic polymer (n₃) and will preferably be directly in adhesive contact with this film.

A diffusing adhesive layer is deemed to be a layer which, when inserted between a UTG sheet and an organic polymer film both having a haze of less than 1%, confers to the laminate obtained (UTG/adhesive layer/film) a haze of at least 50%.

In an embodiment, the haze of the laminated support is preferably at least 70%, in particular at least 90%. In another embodiment, the haze of the laminated support is less than 100%.

The bonding between the UTG sheet and the polymer film must be sufficiently strong to prevent delamination. In a particular embodiment, the laminate support does not include laminated supports where the polymer film is fixed reversibly onto the glass sheet, for example, an adhesive material that would allow for easy peeling without cohesive failure of the adhesive layer.

In a first embodiment of the laminated support, the diffusing adhesive layer includes an organic or organo-mineral matrix having a refractive index n_{2c} that is higher or equal to the refractive index n₃ of the organic polymer film, and diffusing elements having a refractive index n₄ different from n_{2c}, these elements being dispersed in the high-index matrix having a refractive index n_{2c}, which is preferably substantially equal to n₃, the expression “substantially equal” meaning in this context that these two refractive indexes differ by up to 0.07, preferably by up to 0.05, up to 0.03, or up to 0.01.

The organic or organo-mineral matrix has an optically transparent adhesive base. Preferably, pressure sensitive adhesives (PSA) will be used, in particular acrylic PSAs such as S8760, marketed by the Avery Dennison Company.

The refractive index of the organic adhesives can be adjusted by incorporating them with high refractive index mineral particles that are sufficiently small so as to be non-diffusing. These non-diffusing particles are preferably smaller than 50 nm and are for example TiO₂ or ZrO₂ nanoparticles, preferably ZrO₂, the latter being particularly preferred due to their very low absorption of visible light. The non-diffusing particles may be at least 1 nm. The non-diffusing nanoparticle content of the nanocomposite (organic adhesive+nanoparticles) is typically between 30% and 75% by volume, preferably between 50% and 70% by volume and in particular between 60% and 65% by volume.

The high-index organic or organo-mineral matrix (n_{2c}) may also contain diffusing elements. Diffusing elements mean elements with an equivalent diameter of 100 nm or more. Diffusing elements are for example solid particles preferably having a higher refractive index than that of the organic or organo-mineral matrix, for example TiO₂ or ZrO₂ particles. It is also possible, however, to envisage the incorporation of particles with a lower refractive index, such as silica particles, or even the incorporation of hollow spheres, for example hollow glass or organic polymer spheres.

In this first embodiment, the diffusing adhesive layer is therefore a monolayer directly in adhesive contact with the UTG sheet on the one hand and the organic polymer film on the other.

In the present patent, the expression “directly in adhesive contact” does not exclude however the presence of any coatings or compounds applied prior to bonding to the UTG sheet or organic polymer film, for example to improve the adhesive contact.

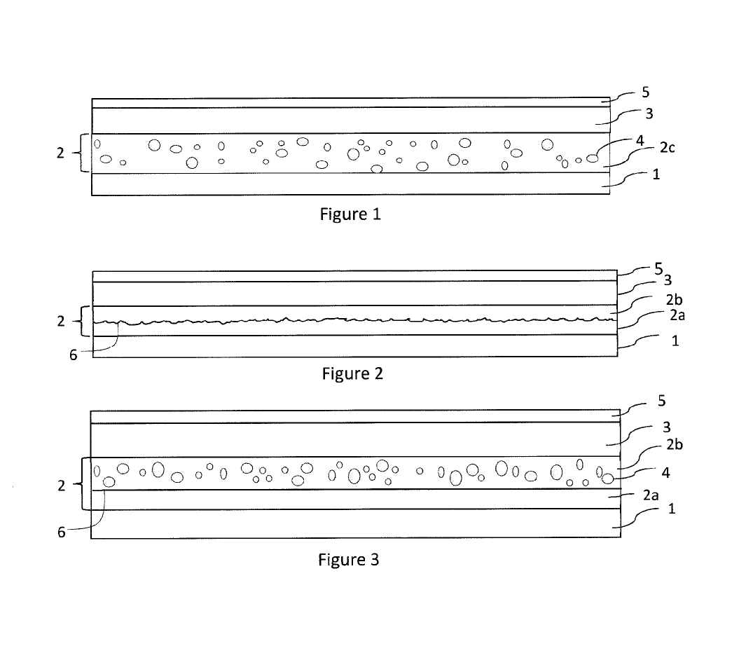

To aid in understanding the first embodiment, a laminated support in FIG. 1 illustrates a particular embodiment that does not limit the scope of the present invention. The laminated support comprises an ultra thin mineral glass sheet 1 having a thickness of less than 300 microns, bonded to a transparent organic polymer film 3 by means of a diffusing adhesive layer 2. This adhesive layer comprises a transparent matrix 2c, having a refractive index n_{2c} greater than or equal to the refractive index n₃ of the organic polymer film 3, in which are dispersed diffusing elements 4. An electro-conductive transparent layer 5 is placed on the organic polymer film 3. This layer has sufficient conductivity to play the role of transparent electrode in the OLED manufactured from such a laminated support.

In a second embodiment, a laminated support is similar to the laminated support of the first embodiment except that a different adhesive layer is used. The diffusing adhesive layer of the second embodiment includes:
a first sub-layer, organic or organo-mineral, with a refractive index n₂ₐ in contact with the mineral glass sheet, and
a second sub-layer, organic or organo-mineral, with a refractive index n_{2b} in contact with the transparent organic polymer film,
   wherein the refractive index n₂ₐ of the first sub-layer is lower than refractive index n_{2b} of the second sub-layer.
   In a particular embodiment, the diffusing adhesive layer may only include the first and second sub-layers.

These two sub-layers are preferably directly in adhesive contact respectively with the UTG sheet and with the high-index stretched organic polymer film. Index n₂ₐ of the first sub-layer is preferably substantially equal to index n₁ of the glass sheet, and index n_{2b} of the second sub-layer is preferably substantially equal to index n₃ of the organic polymer film. The expression “substantially equal” meaning in this context that the refractive indices differ by up to 0.02 or up to 0.01.

In this second embodiment, the interface between the first and second sub-layers is a diffusing textured interface. Its roughness profile (λ_{c}=0.8 mm) has an arithmetical mean deviation Rₐ, determined by image analysis of a cross section of the laminated support, of between 0.1 micron and 30 microns, and an average width of the profile elements Rₛₘ of between 0.1 micron and 100 microns.

In order to manufacture the diffusing adhesive layer of this second embodiment, preferably a low-refractive-index PSA adhesive will be used for the sub-layer (n₂ₐ) in contact with the UTG and a thermocurable or photocurable adhesive for the high-refractive-index sub-layer (n_{2b}) in contact with the polymer film. The thermocurable or photocurable adhesives for the high-index sub-layer are known and can for example be adhesives based on acrylic, styrene, vinyl, epoxide, urethane and ester monomers and/or oligomers. These compositions cure by radical polymerization initiated by UV radiation or heating.

Each sub-layer is placed on the substrate with which it contacts, the high-index sub-layer is textured, before or after curing, with the aid of an appropriate texturization means such as embossing, and then the two substrates are bonded together by lamination.

As with the matrix of the first embodiment, the high-index sub-layer may contain non-diffusing particles such as TiO₂ and ZrO₂ particles.

FIG. 2 represents a second embodiment of the laminated support. In this embodiment, the diffusing adhesive layer 2 includes two transparent sub-layers 2a, 2b. The first sub-layer 2a is in direct adhesive contact with the ultra thin glass sheet 1 and has a refractive index n₂ₐ substantially identical to that of the glass sheet. The second sub-layer 2b is in direct adhesive contact with the polymer film 3. Its refractive index n₃ is substantially identical to that of the polymer film 3. In another embodiment, the first sub-layer 2a may have a refractive index n₂ₐ that is higher than refractive index n₁ of the glass sheet. In a particular embodiment, the first sub-layer 2a may have a refractive index n₂ₐ that is at most 0.07, at most 0.05, or at most 0.03 higher than refractive index n₁ of the glass sheet. In a further embodiment, the second sub-layer 2b may have a refractive index n₂ₐ that is less than refractive index n₃ of the organic polymer layer 3. In a particular embodiment, the second sub-layer 2b may have a refractive index n₂ₐ that is at most 0.07, at most 0.05, or at most 0.03 lower than refractive index n₃ of the organic polymer layer. These two sub-layers 2a, 2b may not contain diffusing elements. The diffusing nature of the adhesive layer 2 is achieved by the roughness of the interface 6 between the two sub-layers.

In a third embodiment of the diffusing adhesive layer of the laminated support, the interface between the first and second sub-layer is textured and the second high-refractive-index sub-layer contains diffusing elements having a refractive index n₄ different from n_{2b}. This third embodiment therefore differs from the second embodiment solely due to the fact that the high-index sub-layer (n_{2b}) contains diffusing elements, for example TiO₂ or ZrO₂ particles having a mean equivalent diameter of 100 nm or larger. As with the second embodiment, the matrix of the high-index sub-layer can be an organo-mineral matrix with an organic adhesive base with non-diffusing particles that have the function of adjusting the refractive index.

As with the second embodiment, preferably a PSA will be used for the low-refractive-index sub-layer (n₂ₐ) in contact with the UTG and a thermocurable or photocurable adhesive for the high-refractive-index sub-layer (n_{2b}) in contact with the polymer film. During the manufacture of the laminate, each sub-layer is placed on the substrate with which it contacts, the high-index sub-layer is textured, before or after curing, with the aid of an appropriate texturizing means, then the two substrates are bonded together by lamination.

Lastly, in a fourth embodiment, the interface between the two sub-layers is not textured, and thus, the interface itself is not diffusing. The diffusing nature of the adhesive layer is ensured solely by the diffusing elements present in the second high-index sub-layer (n_{2b}). The adhesives, non-diffusing particles, diffusing particles and method of manufacture are identical to those of the third embodiment, the only difference being the absence of the texturization step of the high-refractive-index sub-layer.

To aid in understanding the fourth embodiment, a laminated support in FIG. 3 shows a fourth embodiment of the laminated support that does not limit the scope of the appended claims. As with FIG. 2, the diffusing adhesive layer 2 bonding the ultra thin glass sheet 1 to the high-index polymer film 3 includes two sub-layers 2a, 2b. The two sub-layers 2a, 2b have a substantially identical refractive index to that of the glass sheet 1 and the organic polymer film 3 respectively. Alternatively, the two sub-layers 2a and 2b may have refractive indices that are different to that of the glass sheet 1 and organic polymer film 3 as previously described with respect to the second embodiment. The interface 6 between these two sub-layers is not rough and therefore not diffusing. The sub-layer 2b having a higher refractive index than the sub-layer 2a contains diffusing elements 4.

The laminated support for flexible optoelectronic devices may also comprise a transparent electro-conductive layer serving as an electrode for the optoelectronic device, notably as a transparent anode. In an embodiment, this transparent electro-conductive layer is in contact with the transparent organic polymer film 3, more precisely with the face of the polymer film opposite the face that is in contact with the diffusing adhesive layer.

It is preferably formed of
a transparent conductive oxide,
a stack of thin layers containing at least one fine metal layer, in particular a silver layer, or
a metal mesh, possibly combined with a transparent conductive oxide layer.

Transparent conductive oxides are known in the art and examples of such materials are aluminum doped zinc oxide (AZO), indium doped tin oxide (ITO), tin and zinc oxide (SnZnO) or tin dioxide (SnO₂). Stacks of thin layers containing layers of silver of a few nanometers thick between dielectric layers are described for example in WO2009/083693. Lastly, metal meshes in contact with the transparent conductive oxides are described for example in patents US 2004/0150326, WO 2005/008800 and WO2009/07182.

The thickness of the transparent conductive layer in contact with the polymer film is typically between 50 and 200 nm.

Another embodiment includes an optoelectronic device containing a laminated substrate as described above. The optoelectronic device is preferably an OLED comprising a stack of organic layers comprising at least one electroluminescent layer (EL). This electroluminescent layer is sandwiched between, on the one hand, an electron injection or electron transport layer (EIL or ETL) located between the EL and a cathode, generally a metal cathode and, on the other hand, a hole injection or hole transport layer (HIL or HTL) located between the EL and the transparent anode formed by the above-described transparent conductive layer.

A laminated support can be manufactured by a method laminating a mineral glass sheet having a thickness of 300 microns or less and a refractive index n₁ of below 1.65, and a transparent organic polymer film having a refractive index n₃ of at least 1.7, by means of a diffusing adhesive layer. In embodiments where the diffusing adhesive layer comprises two distinct sub-layers with an interface, texturized or not texturized, the high-index sub-layer is preferably applied to the organic polymer film and the low-index sub-layer is preferably applied to the UTG sheet. The two substrates, each bearing an adhesive sub-layer, are then laminated together under pressure and/or by application of heat.

When the diffusing adhesive layer is a monolayer of an organic or organo-mineral matrix, and diffusing elements dispersed in this matrix, the high-index adhesive containing the diffusing elements is preferably applied to the polymer film which is then laminated onto the UTG sheet.

### EXAMPLE

Fifty parts by weight of dipentaerythritol pentaacrylate (SR-399 available from Sartomer), 15 parts by weight of pentaerythritol triacrylate (SR-444 available from Sartomer)+solvent (methanol/ethanol mixture)+1.5 parts by weight of Irgacure 184 are mixed together to prepare an adhesive composition (AC) having a solids content of 66.5% by weight.

Zirconium nanoparticles (ZN) functionalized with acrylate groups (50% in PGMEA, Pixelligent), methyl ethyl ketone (MEK) and 400 nm TiO₂ diffusing particles (DuPont Ti-Pure R-101) are incorporated into this composition.

The mixture is exposed for 15 seconds to ultrasound to homogenize the composition.

| Composition | A | B |
|---|---|---|
| AC | 3.18 g | 4.52 |
| ZN | 45.86 | 44.12 |
| MEK | 0.95 | 1.36 |
| TiO₂ Particles | 0.25 | 0.27 |

Each of these compositions A and B is deposited on a film of biaxially stretched Teonex® Q51 PEN film with the aid of a #6 threaded bar (Mayer Rod). The deposited coatings are cured by exposing them for 270 seconds to UV radiation (Dymax 2000 EC Lamp, Mercury Bulb, 40 mW/cm²). After curing, the coatings have a thickness of around 3 microns. The refractive index of the coating obtained with Composition A is 1.75, that obtained with Composition B is 1.77.

A PSA resin (S8760, 48% solution, Dennison Adhesive) is then diluted with isopropanol until a solids content of 24% by weight is reached. This diluted resin is applied with the aid of a Mayer Rod onto the cured coating containing the diffusing particles until a final thickness of around 20 microns is obtained. The PSA layer is dried for 5 minutes at 120° C. then the adhesive face is applied onto an ultra thin glass sheet with the aid of a scraper.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the items as listed below.

### Embodiment 1

A laminated support for flexible optoelectronic devices comprising, in the order indicated, the following elements:
a mineral glass sheet having a thickness of 300 microns or less and a refractive index n₁ below 1.65, below 1.60, or below 1.55,
a diffusing adhesive layer, and
a uniaxially or biaxially stretched transparent organic polymer film with a refractive index n₃, measured in a direction along the film's plane, of 1.7 or more.

### Embodiment 2

The laminated support according to Embodiment 1, wherein the diffusing adhesive layer comprises an organic or organo-mineral matrix having a refractive index n_{2c}≧n₃, and diffusing elements having a refractive index n₄ different from n_{2c}, dispersed in the matrix.

### Embodiment 3

The laminated support according to Embodiment 2, wherein n_{2c} is substantially equal to n₃.

### Embodiment 4

The laminated support according to Embodiment 1, wherein the diffusing adhesive layer comprises:
a first sub-layer that includes an organic or organo-mineral material and has a refractive index n₂ₐ in contact with the mineral glass sheet, and
a second sub-layer that includes an organic or organo-mineral material and has a refractive index n_{2b} in contact with the transparent organic polymer film,
with n₂ₐ<n_{2b}.

### Embodiment 5

The laminated support according to Embodiment 4, wherein n₂ₐ is substantially equal to n₁ and n_{2b} is substantially equal to n₃.

### Embodiment 6

The laminated support according to Embodiment 4, wherein n₂ₐ is different from and within 0.07 of n₁ and n_{2b} is different from and within 0.07 of n₃.

### Embodiment 7

The laminated support according to any one of Embodiments 4 to 6, wherein the interface between the first and second sub-layers is a diffusing textured interface.

### Embodiment 8

The laminated support according to any of Embodiments 4 to 7, wherein the second sub-layer contains diffusing elements having a refractive index n₄ different from n_{2b}.

### Embodiment 9

The laminated support according to any one of the preceding Embodiments, wherein the transparent organic polymer is chosen from polyesters or copolyesters based on 2,6-naphthalenedicarboxylic acid, ethylene glycol acid and possibly one or more comonomers, such as terephthalic acid or a mixture of poly(ethylene naphthalate) (PEN) and poly(ethylene terephthalate) (PET).

### Embodiment 10

The laminated support according to any of the preceding Embodiments, wherein it also includes, on the face of the transparent organic polymer film opposite the one that is in contact with the diffusing adhesive layer, a conductive transparent layer.

### Embodiment 11

The laminated support according to any one of the preceding Embodiments, wherein the diffusing adhesive layer further comprises nanoparticles.

### Embodiment 12

The laminated support of Embodiment 11, wherein the nanoparticles have a refractive index that is greater than the organic or organo-mineral matrix, first sub-layer, or second sub-layer in which the nanoparticles reside.

### Embodiment 13

An optoelectronic device comprising a laminated support according to any one of the preceding Embodiments.

### Embodiment 14

An optoelectronic device of Embodiment 13, further comprising an OLED.

### Embodiment 15

A manufacturing method for a laminated support according to any one of the preceding Embodiments, the method comprises laminating of a mineral glass sheet having a thickness of 300 microns or less and a refractive index n₁ of below 1.65, and a transparent organic polymer film having a refractive index n₃ of at least 1.7, with a diffusing adhesive layer.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A laminated support for flexible optoelectronic devices comprising, in the order indicated, the following elements:
a mineral glass sheet having a thickness of 300 microns or less and a refractive index n₁ below 1.65,
a diffusing adhesive layer, and
a uniaxially or biaxially stretched transparent organic polymer film with a refractive index n₃, measured in a direction along the film's plane, of 1.7 or more.

2. The laminated support according to claim 1, wherein the diffusing adhesive layer comprises an organic or organo-mineral matrix having a refractive index n_{2c}>n₃, and diffusing elements having a refractive index n₄ different from n_{2c}, dispersed in the matrix.

3. The laminated support according to claim 2, wherein n_{2c} is substantially equal to n₃.

4. The laminated support according to claim 1, wherein the transparent organic polymer is chosen from polyesters or copolyesters based on 2,6-naphthalenedicarboxylic acid, ethylene glycol acid and possibly one or more comonomers, such as terephthalic acid or a mixture of poly(ethylene naphthalate) (PEN) and poly(ethylene terephthalate) (PET).

5. The laminated support according to claim 1, wherein it also includes, on the face of the transparent organic polymer film opposite the one that is in contact with the diffusing adhesive layer,
a conductive transparent layer.

6. The laminated support according to claim 1, wherein the diffusing adhesive layer further comprises nanoparticles.

7. The laminated support of claim 1, wherein the nanoparticles have a refractive index that is greater than the organic or organo-mineral matrix, first sub-layer, or second sub-layer in which the nanoparticles reside.

8. The laminated support according to claim 1, wherein the diffusing adhesive layer comprises:
a first sub-layer includes an organic or organo-mineral material and has a refractive index n₂ₐ in contact with the mineral glass sheet, and
a second sub-layer includes organic or organo-mineral material and has a refractive index n_{2b} in contact with the transparent organic polymer film,
with n₂ₐ<n_{2b}.

9. The laminated support according to claim 8, wherein n₂ₐ is substantially equal to n₁ and n_{2b} is substantially equal to n₃.

10. The laminated support according to claim 8, wherein n₂ₐ is different from and within 0.07 of n₁ and n_{2b} is different from and within 0.07 of n₃.

11. The laminated support according to claim 8, wherein the interface between the first and second sub-layers is a diffusing textured interface.

12. The laminated support according to claim 8, wherein the second sub-layer contains diffusing elements having a refractive index n₄ different from n_{2b}.

13. The laminated support according to claim 8, wherein the transparent organic polymer is chosen from polyesters or copolyesters based on 2,6-naphthalenedicarboxylic acid, ethylene glycol acid and possibly one or more comonomers, such as terephthalic acid or a mixture of poly(ethylene naphthalate) (PEN) and poly(ethylene terephthalate) (PET).

14. The laminated support according to claim 8, wherein it also includes, on the face of the transparent organic polymer film opposite the one that is in contact with the diffusing adhesive layer,
a conductive transparent layer, preferably formed of a transparent conductive oxide, a stack of layers containing at least one metal layer or a metal mesh.

15. The laminated support according to claim 14, wherein the diffusing adhesive layer further comprises nanoparticles having a refractive index higher than n_{2c} and higher than n_{2b}.

16. An optoelectronic device comprising a laminated support according to claim 1.

17. An optoelectronic device of claim 16, further comprising an OLED.

18. A manufacturing method for a laminated support according to claim 1, the method comprises laminating of the mineral glass sheet and the transparent organic polymer film with the diffusing adhesive layer.
